(19) United States
(12) Patent Application Publication
(10) Pub. No.: US 2021/0367011 A1
(43) Pub. Date: Nov. 25, 2021

(54) OLED DISPLAY PANEL, MANUFACTURING METHOD THEREOF, AND OLED DISPLAY

(71) Applicant: SHENZHEN CHINA STAR OPTOELECTRONICS SEMICONDUCTOR DISPLAY TECHNOLOGY CO., LTD., Shenzhen (CN)

(72) Inventor: Yifei BING, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/627,786

(22) PCT Filed: Dec. 23, 2019
(86) PCT No.: PCT/CN2019/127641

§ 371 Date: Dec. 31, 2019

(30) Foreign Application Priority Data
Dec. 4, 2019 (CN) 201911226778.3

(51) Int. Cl. H01L 27/32; H01L 51/00; H01L 51/56

(52) U.S. Cl. CPC H01L 27/3246; H01L 2227/323; H01L 51/56; H01L 51/0005

(57) ABSTRACT

The present application discloses an OLED display panel, a manufacturing method thereof, and an OLED display. In this application, by designing that heights of the first bank and the second bank are greater than the height of the third bank, the higher first bank and second bank can block the ink of a large amount for thicker film in the first grooves as much as possible, and in addition, it is also beneficial to block the ink of a small amount for a thinner film to prevent it from flowing toward the first grooves, so as to prevent mixing between inks in which different organic light-emitting materials are dissolved, and thus prevent OLED display panels from the problem of poor light emission such as pixel color shift and color mixing.

### BACKGROUND OF INVENTION

### Field of Invention

The present application relates to a field of display, and in particular to an organic light-emitting diode (OLED) display panel, a manufacturing method thereof, and an organic light-emitting diode (OLED) display.

### Description of Prior Art

Inkjet printing is an important process for manufacturing OLED display panels. However, due to different thickness of a material and layer required for each color of an organic light-emitting diode (OLED) device and the particularity of a inkjet printing process, inks of different light-emitting materials often mix. As a result, the OLED display panel suffers from problems of poor light emission, such as pixel color shift and color mixing.

In the prior art, when an organic light-emitting layer is prepared by inkjet printing, there exists the problem of poor light emission caused by the mixing of inks with different colors between adjacent pixel areas.

### SUMMARY OF INVENTION

The method of manufacturing the OLED display panel provided in the present application includes:

providing a substrate;

forming anode electrodes and a pixel definition layer on the substrate, wherein the pixel definition layer surrounds a plurality of grooves arranged in an array, and the anode electrodes are located in the grooves in one-to-one correspondence, wherein the grooves include a plurality of first grooves, a plurality of second grooves, and a plurality of third grooves, the pixel definition layer includes a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;

dropping an ink with a first organic light-emitting material dissolved therein into the first grooves by inkjet printing for film formation to form a first organic light-emitting layer, dropping an ink with a second organic light-emitting material dissolved therein into the second grooves by inkjet printing for film formation to form a second organic light-emitting layer, and dropping an ink with a third organic light-emitting material dissolved therein into the third grooves by inkjet printing for film formation to form a third organic light-emitting layer;

forming an electron transport layer covering the first organic light-emitting layer, the second organic light-emitting layer, the third organic light-emitting layer, and the pixel definition layer; and

forming a cathode electrode covering the electron transport layer.

An organic light-emitting diode (OLED) display panel provided in the present application includes:

a substrate;

anode electrodes and a pixel definition layer disposed on the substrate, wherein the pixel definition layer surrounds a plurality of grooves arranged in an array, and the anode electrodes are located in the grooves in one-to-one correspondence, wherein the grooves include a plurality of first grooves, a plurality of second grooves, and a plurality of third grooves, the pixel definition layer includes a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;

an organic light-emitting layer including a first organic light-emitting layer, a second organic light-emitting layer, and a third organic light-emitting layer, wherein thicknesses of the second organic light-emitting layer and the third organic light-emitting layer are less than a thickness of the first organic light-emitting layer, the first organic light-emitting layer is located in the first grooves, the second organic light-emitting layer is located in the second grooves, and the third organic light-emitting layer is located in the third grooves;

an electron transport layer covering the first organic light-emitting layer, the second organic light-emitting layer, the third organic light-emitting layer, and the pixel definition layer; and

a cathode electrode covering the electron transport layer.

An organic light-emitting diode (OLED) display provided in the present application includes an integrated circuit and an organic light-emitting diode display panel, wherein the integrated circuit is connected to the organic light-emitting diode display panel, and the organic light-emitting diode display panel includes:

a substrate;

anode electrodes and a pixel definition layer disposed on the substrate, wherein the pixel definition layer surrounds a plurality of grooves arranged in an array, and the anode electrodes are located in the grooves in one-to-one correspondence, wherein the grooves include a plurality of first grooves, a plurality of second grooves, and a plurality of third grooves, the pixel definition layer includes a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;

an organic light-emitting layer including a first organic light-emitting layer, a second organic light-emitting layer, and a third organic light-emitting layer, wherein thicknesses of the second organic light-emitting layer and the third organic light-emitting layer are less than a thickness of the first organic light-emitting layer, the first organic light-emitting layer is located in the first grooves, the second organic light-emitting layer is located in the second grooves, and the third organic light-emitting layer is located in the third grooves;

an electron transport layer covering the first organic light-emitting layer, the second organic light-emitting layer, the third organic light-emitting layer, and the pixel definition layer; and

a cathode electrode covering the electron transport layer.

In the present invention, by designing that heights of the first bank and the second bank are greater than the height of the third bank, the higher first bank and second bank can block the ink of a large amount for thicker film in the first grooves as much as possible, and in addition, it is also beneficial to block the ink of a small amount for a thinner film to prevent it from flowing toward the first grooves, so as to prevent mixing between inks in which different organic light-emitting materials are dissolved, and thus prevent OLED display panels from the problem of poor light emission such as pixel color shift and color mixing.

### BRIEF DESCRIPTION OF DRAWINGS

FIG. 1 is a schematic flowchart of a method for manufacturing an organic light-emitting diode (OLED) display panel according to an embodiment of the present application.

FIG. 2 is a schematic diagram of dripping ink by inkjet printing according to an embodiment of the present application.

FIG. 3 is a schematic cross-sectional view of an organic light-emitting diode (OLED) display panel according to an embodiment of the present application.

FIG. 4 is a schematic cross-sectional view of an organic light-emitting diode (OLED) display panel according to another embodiment of the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application. Without conflict, the following embodiments and their technical features can be permutated with each other.

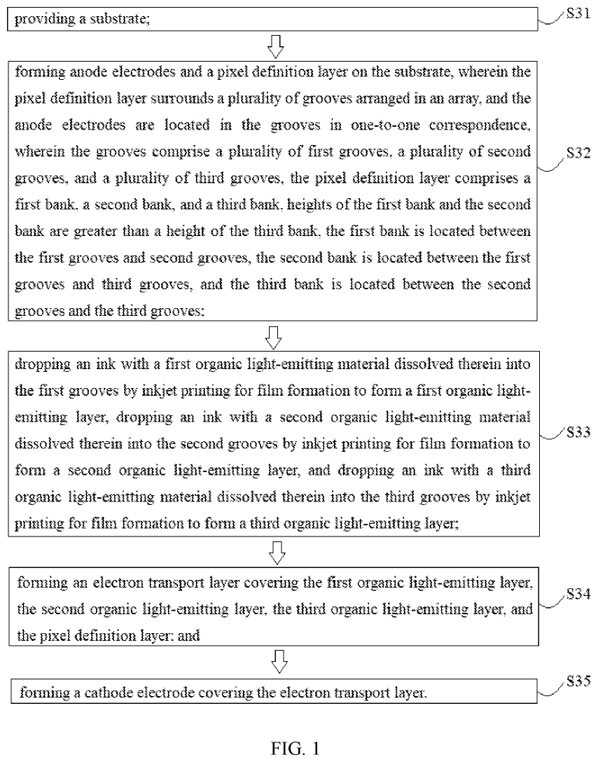

FIG. 1 is a schematic flowchart of a method for manufacturing an organic light-emitting diode (OLED) display panel according to an embodiment of the present application. Referring to FIG. 1, a method of manufacturing the OLED display panel includes the following steps:

S31: providing a substrate.

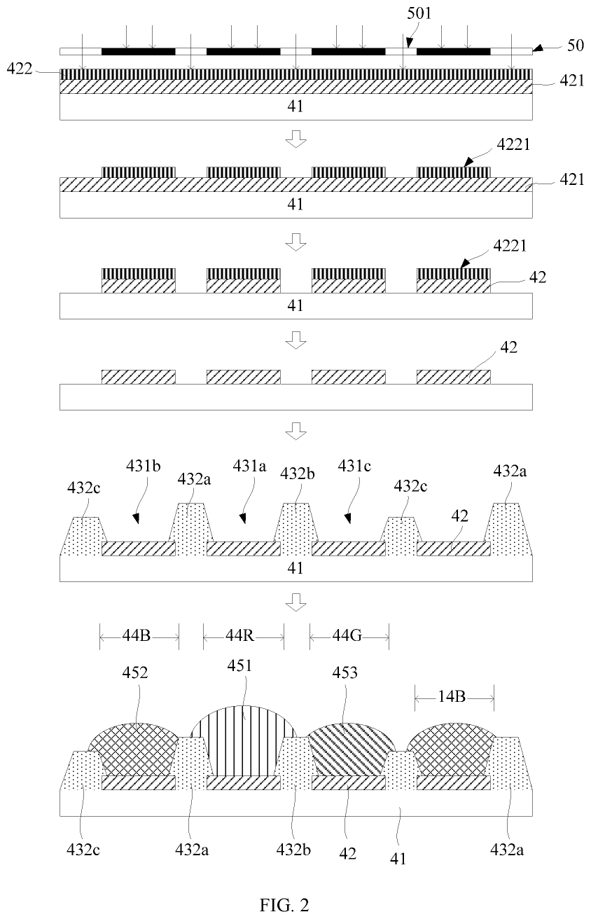

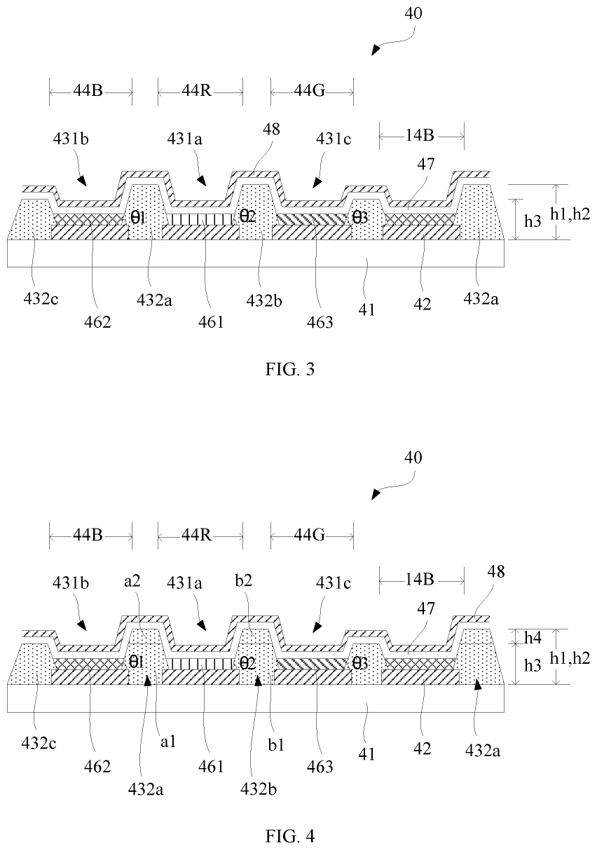

Referring to FIG. 2 and FIG. 3, the substrate 41 is used to carry various structural layers and electronic components of the OLED display panel 40. In order to adapt to bendable characteristics of the OLED display panel 40, the substrate 41 may be a flexible plate with bendable characteristics, mainly made of a material including, but not limited, to polyimide (PI).

The substrate 41 may be covered with a buffer layer having a water and oxygen blocking function, and mainly made of a material including, but not limited to, silicon nitride compounds (SiNx), silicon oxide compounds (SiOx), and silicon nitride oxide. (SiOxNy), etc. In addition, the buffer layer may have a thickness between 500 and 1000 nanometers. When a buffer layer is provided, each of the structural layers and electronic components such as the anode electrode 42 and the pixel definition layer, prepared in the following steps, are located on the buffer layer. Of course, for the structural design of the OLED display panel 40 without a buffer layer, the anode electrode 42 and the pixel definition layer described below are directly disposed on the substrate 41. The following description takes the structural design of the OLED display panel 40 without a buffer layer as an example for description.

S32: forming anode electrodes and a pixel definition layer on the substrate, wherein the pixel definition layer surrounds a plurality of grooves arranged in an array, and the anode electrodes are located in the grooves in one-to-one correspondence, wherein the grooves include a plurality of first grooves, a plurality of second grooves, and a plurality of third grooves, the pixel definition layer includes a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves.

Referring to FIG. 2, in this embodiment, the anode electrode 42 can be formed first, and then the pixel definition layer is formed. For example, the anode electrodes 42 and pixel definition layer can be respectively formed by a photomask etching process (including film formation, exposure, development, and etching processes).

The process of forming the anode electrode 42 by using a photomask etching process is performed specifically as follows:

First, a blanket conductive layer 421 and a photoresist layer 422 covering the conductive layer 421 are formed on the substrate 41. The conductive layer 421 may be made of a material with good conductivity and high corrosion resistance, such as a metal material, including but not limited to molybdenum, nickel, palladium, cobalt, tungsten, rhodium, titanium, chromium, gold, silver, platinum, and the like. Of course, in order to further improve its conductivity, the conductive layer 421 may employ a multi-layered metal stacked structure, such as a three-layered metal structure of molybdenum, aluminum, and molybdenum, or a three-layered metal structure of nickel, copper, and nickel, or a three-layered metal structure of molybdenum, copper, and molybdenum, or a three-layered metal structure of nickel, aluminum, and nickel. By providing a three-layered metal conductive structure, not only the conductivity of the conductive layer 421 and the anode electrode 42 made therefrom can be improved, but also the corrosion resistance of the conductive layer 421 and the anode electrode 42 can be improved.

Next, the photoresist layer 422 is exposed by using photomasks 50 to obtain a photoresist layer 4221 having a predetermined pattern. The photoresist layer 4221 having a predetermined pattern exposes a portion to be etched of the conductive layer 421. Specifically, the photomasks 50 are provided with a light-transmitting area 501. During the exposure process, the photomasks 50 are disposed at intervals above the photoresist layer 422, and the pattern of the light-transmitting area 501 is consistent with the final target pattern to be etched, wherein light passes through the light-transmitting region 501 and is irradiated to the photoresist layer 422 for exposure. The exposed portion of the photoresist layer 422 is removed by a developing solution, while the unexposed portion of the photoresist layer 422 cannot be removed by the developing solution, thus finally preserved. The photoresist layer 422 is converted into a photoresist layer 4221 having a predetermined pattern in a top view, wherein a portion of the photoresist layer 422 that is removed by the developing solution exposes the portion to be etched of the conductive layer 421.

Then, a portion of the conductive layer 421 that is not covered by the photoresist layer 4221 is removed by etching. In this embodiment, the portion of the conductive layer 421 that is not covered by the photoresist layer 4221 may be removed by dry etching or wet etching. As to wet etching, a portion of the conductive layer 421 covered by the photoresist layer 4221 is in full contact with an etching solution and subjected to a dissolution reaction, so as to be completely removed, while the portion not covered by the photoresist layer 4221 fails to be in contact with the etching solution and is finally retained. As a result, the conductive layer 421 is etched and transformed into the anode electrode 42 having a predetermined pattern.

Finally, the photoresist layer 4221 is removed by ashing to obtain the anode electrode 42.

The pixel definition layer can be obtained through a mask and a film formation process such as physical vapor deposition (PVD), pulsed laser deposition (PLD), and magnetron sputtering. Of course, the pixel definition layer can also be prepared by using a photomask etching process. The process and principle can be referred to above, and will not be repeated herein for brevity.

Still referring to FIG. 2, the pixel definition layer surrounds a plurality of grooves arranged in an array, and the anode electrodes 42 are located in the grooves in one-to-one correspondence. These grooves are used to define the pixel areas of the OLED display panel 40. Taking the pixel areas of three colors including red pixel areas 44R, green pixel areas 44G, and blue pixel areas 44B as an example, these grooves can be divided into first grooves 431a configured to define the red pixel areas 44R, second grooves 431b configured to define the blue pixel areas 44B, and third grooves 431c configured to define the green pixel areas 44G.

The pixel definition layer may be divided into a first bank 432a, a second bank 432b, and a third bank 432c. The first bank 432a is located between the first groove 431a and the second groove 431b, the second bank 432b is located at between the first groove 431a and the third groove 431c, and the third bank 432c is located between the second groove 431b and the third groove 431c.

Referring to FIG. 3, a height h1 of the first bank 432a and a height h2 of the second bank 432b are equal to each other and greater than a height h3 of the third bank 432c, that is, h1=h2>h3.

It should be understood that, in other embodiments, the height h1 of the first bank 432a and the height h2 of the second bank 432b may be different, but both greater than the height h3 of the third bank 432c, that is, h1≠h2, and h1>h3, h2>h3.

S33: dropping an ink with a first organic light-emitting material dissolved therein into the first grooves by inkjet printing for film formation to form a first organic light-emitting layer, dropping an ink with a second organic light-emitting material dissolved therein into the second grooves by inkjet printing for film formation to form a second organic light-emitting layer, and dropping an ink with a third organic light-emitting material dissolved therein into the third grooves by inkjet printing for film formation to form a third organic light-emitting layer.

Still referring to FIG. 2, the first organic light-emitting material is used to emit red light, the second organic light-emitting material is used to emit blue light, and the third organic light-emitting material is used to emit green light. In an embodiment of the present application, the ink 451 in which the first organic light-emitting material is dissolved, the ink 452 in which the second organic light-emitting material is dissolved, and the ink 453 in which the third organic light-emitting material is dissolved can be dropped into the first grooves 431a, the second grooves 431b, and the third grooves 431c. The inks in which the organic light-emitting material is dissolved can also be dropped into the three types of grooves in a predetermined order. For example, the ink 451 in which the first organic light-emitting material is dissolved can be dropped first into the first grooves 431a, then the ink 452 in which the second organic light-emitting material is dissolved can be dropped into the second grooves 431b, and finally the ink 453 in which the third organic light-emitting material is dissolved can be dropped into the third grooves 431c.

Please refer to FIG. 2 and FIG. 3. In an embodiment of the present application, the ink dropped into the three types of grooves is further dried, so that the ink 451 in which the first organic light-emitting material is dissolved is formed into the first organic light-emitting layer 461, the ink 452 in which the second organic light-emitting material is dissolved is formed into the second organic light-emitting layer 462, and the ink 453 in which the third organic light-emitting material is dissolved is formed into the third organic light-emitting layer 463. The first organic light-emitting layer 461, the second organic light-emitting layer 462, and the third organic light-emitting layer 463 constitute the organic light-emitting layer of the OLED display panel 40.

S34: forming an electron transport layer covering the first organic light-emitting layer, the second organic light-emitting layer, the third organic light-emitting layer, and the pixel definition layer.

S35: forming a cathode electrode covering the electron transport layer.

In an embodiment of the present application, an electron transport layer (ETL) 47 and a cathode 48 may be sequentially formed through a film formation process including PVD, PLD, sputtering, etc.

It should be understood that the foregoing steps have not produced all structural components of the OLED display panel 40. For example, the OLED display panel 40 may further include a hole injection layer (HIL), a hole transport layer (HTL), and an electron injection layer (EIL), wherein the hole injection layer is formed on the anode electrode 42, the hole transport layer is formed between the hole injection layer and the organic light-emitting layer, and the electron injection layer is formed between the electron transport layer 47 and the cathode electrode 48. Manufacturing process of these undescribed structural parts can refer to the prior art.

The OLED display panel 40 can be obtained through the foregoing step S31 to step S35.

Considering that the thickness of the organic light-emitting layer (i.e., the first organic light-emitting layer 461) of the red pixel of the OLED display panel 40 is relatively largest, and the thicknesses of the organic light-emitting layer (i.e., the second organic light-emitting layer 462) of the blue pixel and the organic light-emitting layer (i.e., the third organic light-emitting layer 463) are equal to each other, in an embodiment of the present application, by designing that the height h1 of the first bank 432a and the height h2 of the second bank 432b are both greater than the height h3 of the third bank 432c, that is, h1>h3 and h2>h3, and an amount of the ink 451 in which the red organic light-emitting material is dissolved is also larger than an amount of the ink 452 in which the blue organic light-emitting material is dissolved and an amount of the ink 453 in which the green organic light-emitting material is dissolved, the higher first bank 432a and second bank 432b can block the ink 451 of a large amount in the first grooves 431a as much as possible, and in addition, it is also beneficial to block the ink 452 an the ink 453 of small amounts to prevent them from flowing toward the first grooves 431a, so as to prevent mixing between the inks 451, 452, and 453, and thus prevent OLED display panels 40 from the problem of poor light emission such as pixel color shift and color mixing.

The height h3 of the third bank 432c may be equal to the height of the pixel definition layer of the prior art. In this case, an embodiment of the present application may be regarded as elevating the portion of the existing pixel definition layer 13 located around the red pixel areas 14R.

It should be understood that the corresponding relationships between the red pixel areas 44R, the blue pixel areas 44B, and the green pixel areas 44G and the first grooves 431a, the second grooves 431b, and the second grooves 431c are merely examples, and other embodiments may also provide various grooves configured to define pixel areas of other colors. Accordingly, a color of the organic light-emitting material dissolved in the ink also changes. However, no matter how the pixel areas of colors are arranged, in an embodiment of the present application, by designing that the height h1 of the first bank 432a and the height h2 of the second bank 432b are both greater than the height h3 of the third bank 432c, the higher first bank 432a and the second bank 432b can block the ink 451 of a large amount for a thicker film in the first grooves 431a as much as possible, and in addition, it is also beneficial to block the ink 452 and the ink 453 of small amounts for thinner films to prevent it from flowing toward the first grooves, so as to prevent mixing between inks in which different organic light-emitting materials are dissolved, and thus prevent OLED display panels from the problem of poor light emission such as pixel color shift and color mixing.

Still referring to FIG. 3, an inclination angle θ1 of the first bank 432a and an inclination angle θ2 of the second bank 432b are equal, and both greater than an inclination angle θ3 of the third bank 432c, that is, θ1=θ2>θ3, where the inclination angles θ1, θ2, and θ3 are all acute angles. In this case, slopes of the first bank 432a and the second bank 432b are relatively steep, such that the ink 451 in the first grooves 431a is not easy to overflow, and the ink 452 in the second grooves 431b is not easy to overflow to the top of the first bank 432a, and the ink 453 in the third grooves 431c is also not easy to overflow to the top of the second bank 432b, which is more conducive to preventing the mixing of inks with different organic light-emitting materials dissolved therein through the first bank 432a and the second bank 432b, and further beneficial to avoiding the phenomenon of poor pixel light emission of the OLED display panel 40.

In a specific embodiment, a surface of the substrate 41 may be hydrophilic, and surfaces of the first bank 432a, the second bank 432b, and the third bank 432c are all hydrophobic. In this case, the inks 451, 452, and 453 are not easy to overflow to the corresponding banks, but are more likely to overflow to the substrate 41. Therefore, it is more conducive to preventing the mixing of inks with different organic light-emitting materials dissolved therein through the first bank 432a and the second bank 432b, and further beneficial to avoiding the phenomenon of poor pixel light emission of the OLED display panel 40.

FIG. 4 is a schematic cross-sectional view of an organic light-emitting diode (OLED) display panel according to another embodiment of the present application. For structural elements with the same names, the embodiments of the present application use the same reference numerals for identification. Different from the description of the foregoing embodiments, in the OLED display panel 40 of this embodiment, the second bank 432b and the third bank 432c are not formed by a same photomask etching process, but are formed by two photomask etching processes.

In particular, the first bank 432a includes a first main bank a1 and a first sub-bank a2 located on the first main bank al, and the second bank 432b includes a second main bank b1 and a second sub-bank b2 on the second main bank b1. The first main bank a1, the second main bank b1, and the third bank 432c may have a same height of h3. The first sub-bank a2 and the second sub-bank b2 may have a same height of h4, and h4+h3=h1=h2. In this case, the first main bank a1, the second main bank b1, and the third bank 432c are made by the same photomask etching process, and the first sub-bank a2 and the second sub-bank b2 are made together by another photomask etching process.

The difference between the OLED display panels 40 of the embodiments shown in FIG. 4 and FIG. 3 is only that numbers of processes of forming the second bank 432b and the third bank 432c are different, but the heights of the second bank 432b and the third bank 432c have not changed. Therefore, the OLED display panel 40 of the embodiment shown in FIG. 4 also reserves the beneficial effects of the foregoing embodiment shown in FIG. 3.

When the height h1 of the first bank 432a and the height h2 of the second bank 432b are not equal, the heights of the first sub-bank a2 and the second sub-bank b2 are not equal. In this case, the first main bank a1, the second main bank b1, and the third bank 432c are made by the same photomask etching process, the first sub-bank a2 is made by another photomask etching process, and the second sub-bank b2 is made by yet another photomask etching process.

An embodiment of the present application also provides an organic light-emitting diode (OLED) display, which includes an integrated circuit (IC) and an organic light-emitting diode (OLED) display panel connected to the integrated circuit, wherein the OLED display panel may have a structure same as that of the OLED display panel 40 according to any one of the foregoing embodiments. Therefore, in the OLED display, by designing that heights of the first bank and the second bank is greater than the height of the third bank, the higher first bank and the second bank can block the ink of a large amount for a thicker film in the first grooves as much as possible, and in addition, it is also beneficial to block the ink of a small amount with a thinner film to prevent it from flowing toward the first grooves, so as to prevent mixing between inks in which different organic light-emitting materials are dissolved, and thus prevent OLED display panels from the problem of poor light emission such as pixel color shift and color mixing.

Although the present application has been shown and described with respect to one or more implementations, those skilled in the art will recognize equivalent variations and modifications upon reading and understanding the present specification and drawings. The present application includes all such modifications and alterations and is limited only by the scope of the following claims. In particular with regard to the various functions performed by the aforementioned components, the terminology used to describe such components is intended to correspond to any component (unless otherwise indicated) that performs the specified function of the component (e.g., it is functionally equivalent), and even if it is not structurally equivalent to the disclosed structure that performs the functions in the exemplary implementation of the present specification shown herein.

That is, the above are only examples of the present application, and thus do not limit the patent scope of the present application. Any equivalent structure or equivalent process transformation made by using the description of the application and the contents of the drawings, such as mutual combination of technical features between the embodiments or direct or indirect use of technical features in other related technical fields, is similarly included in the scope of patent protection of the present application.

In the description of the present invention, it is to be understood that the terms “center”, “longitudinal”, “transverse”, “length”, “width”, “thickness”, “upper”, “lower”, “front”, “post”, “left”, “right”, “vertical”, “horizontal”, “top”, “bottom”, “inside”, “outside”, etc. demonstrating the orientation or positional relationship of the indications is based on the orientation shown in the drawings Or, the positional relationship is merely for the convenience of the description of the present invention and the simplification of the description, and is not intended to imply that the device or the component of the present invention has a specific orientation and is constructed and operated in a specific orientation, thus being not to be construed as limiting the present invention. Moreover, the terms “first” and “second” are used for descriptive purposes only and are not to be construed as indicating or implying a relative importance or not to implicitly indicate a number of technical features indicated. Thus, features defined by “first” or “second” may include one or more of the described features either explicitly or implicitly. In the description of the present invention, the meaning of “a plurality” is two or more unless specifically defined otherwise.

In the present application, the term “exemplary” is used to mean “serving as an example, illustration, or description.” Any embodiment described as “exemplary” in the present application is not necessarily to be construed as preferred or advantageous over other embodiments. In order to enable any person skilled in the art to implement and use the present invention, the following description is given. In the following description, details are set forth for the purpose of explanation. It should be understood by one of ordinary skill in the art that the present invention may be implemented without the use of these specific details. In other embodiments, well-known structures and procedures are not described in detail to avoid obscuring the description of the present invention with unnecessary details. Accordingly, the present invention is not intended to be limited to the embodiments shown, but is to be accorded the widest scope consistent with the principles and features disclosed herein.

What is claimed is:

1. A method of manufacturing an organic light-emitting diode display panel, comprising:
providing a substrate;
forming anode electrodes and a pixel definition layer on the substrate, wherein the pixel definition layer surrounds a plurality of grooves arranged in an array, and the anode electrodes are located in the grooves in one-to-one correspondence, wherein the grooves comprise a plurality of first grooves, a plurality of second grooves, and a plurality of third grooves, the pixel definition layer comprises a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;
dropping an ink with a first organic light-emitting material dissolved therein into the first grooves by inkjet printing for film formation to form a first organic light-emitting layer, dropping an ink with a second organic light-emitting material dissolved therein into the second grooves by inkjet printing for film formation to form a second organic light-emitting layer, and dropping an ink with a third organic light-emitting material dissolved therein into the third grooves by inkjet printing for film formation to form a third organic light-emitting layer;
forming an electron transport layer covering the first organic light-emitting layer, the second organic light-emitting layer, the third organic light-emitting layer, and the pixel definition layer; and
forming a cathode electrode covering the electron transport layer.

2. The method according to claim 1, wherein inclination angles of the first bank and the second bank are equal to each other and larger than an inclination angle of the third bank.

3. The method according to claim 1, wherein a surface of the substrate is hydrophilic, and surfaces of the first bank, the second bank, and the third bank are all hydrophobic.

4. The method according to claim 1, wherein the first and second banks have a same thickness.

5. The method according to claim 1, wherein the first bank comprises a first main bank and a first sub-bank located on the first main bank, the second bank comprises a second main bank and a second sub-bank located on the second main bank, and the first main bank, the second main bank, and the third bank have a same height.

6. The method according to claim 5, wherein the first sub-bank and the second sub-bank have a same height.

7. An organic light-emitting diode display panel, comprising:
a substrate;
anode electrodes and a pixel definition layer disposed on the substrate, wherein the pixel definition layer surrounds a plurality of grooves arranged in an array, and the anode electrodes are located in the grooves in one-to-one correspondence, wherein the grooves comprise a plurality of first grooves, a plurality of second grooves, and a plurality of third grooves, the pixel definition layer comprises a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;
an organic light-emitting layer comprising a first organic light-emitting layer, a second organic light-emitting layer, and a third organic light-emitting layer, wherein thicknesses of the second organic light-emitting layer and the third organic light-emitting layer are less than a thickness of the first organic light-emitting layer, the first organic light-emitting layer is located in the first grooves, the second organic light-emitting layer is located in the second grooves, and the third organic light-emitting layer is located in the third grooves;
an electron transport layer covering the first organic light-emitting layer, the second organic light-emitting layer, the third organic light-emitting layer, and the pixel definition layer; and
a cathode electrode covering the electron transport layer.

8. The organic light-emitting diode display panel according to claim 7, wherein the first bank and second bank have a same height, and the thicknesses of the second organic light-emitting layer and third organic light-emitting layer have a same thickness.

9. The organic light-emitting diode display panel according to claim 8, wherein inclination angles of the first bank and the second bank are equal to each other and larger than an inclination angle of the third bank.

10. The organic light-emitting diode display panel according to claim 8, wherein a surface of the substrate is hydrophilic, and surfaces of the first bank, the second bank, and the third bank are all hydrophobic.

11. The organic light-emitting diode display panel according to claim 8, wherein the first bank comprises a first main bank and a first sub-bank located on the first main bank, the second bank comprises a second main bank and a second sub-bank located on the second main bank, and the first main bank, the second main bank, and the third bank have a same height.

12. The organic light-emitting diode display panel according to claim 11, wherein the first sub-bank and the second sub-bank have a same height.

13. An organic light-emitting diode display, comprising an integrated circuit and an organic light-emitting diode display panel, wherein the integrated circuit is connected to the organic light-emitting diode display panel, and the organic light-emitting diode display panel comprises:
a substrate;
anode electrodes and a pixel definition layer disposed on the substrate, wherein the pixel definition layer surrounds a plurality of grooves arranged in an array, and the anode electrodes are located in the grooves in one-to-one correspondence, wherein the grooves comprise a plurality of first grooves, a plurality of second grooves, and a plurality of third grooves, the pixel definition layer comprises a first bank, a second bank, and a third bank, heights of the first bank and the second bank are greater than a height of the third bank, the first bank is located between the first grooves and second grooves, the second bank is located between the first grooves and third grooves, and the third bank is located between the second grooves and the third grooves;
an organic light-emitting layer comprising a first organic light-emitting layer, a second organic light-emitting layer, and a third organic light-emitting layer, wherein thicknesses of the second organic light-emitting layer and the third organic light-emitting layer are less than a thickness of the first organic light-emitting layer, the first organic light-emitting layer is located in the first grooves, the second organic light-emitting layer is located in the second grooves, and the third organic light-emitting layer is located in the third grooves;
an electron transport layer covering the first organic light-emitting layer, the second organic light-emitting layer, the third organic light-emitting layer, and the pixel definition layer; and
a cathode electrode covering the electron transport layer.

14. The organic light-emitting diode display according to claim 13, wherein the first bank and second bank have a same height, and the thicknesses of the second organic light-emitting layer and third organic light-emitting layer have a same thickness.

15. The organic light-emitting diode display according to claim 14, wherein inclination angles of the first bank and the second bank are equal to each other and larger than an inclination angle of the third bank.

16. The organic light-emitting diode display according to claim 14, wherein a surface of the substrate is hydrophilic, and surfaces of the first bank, the second bank, and the third bank are all hydrophobic.

17. The organic light-emitting diode display according to claim 14,wherein the first bank comprises a first main bank and a first sub-bank located on the first main bank, the second bank comprises a second main bank and a second sub-bank located on the second main bank, and the first main bank, the second main bank, and the third bank have a same height.

18. The organic light-emitting diode display according to claim 17, wherein the first sub-bank and the second sub-bank have a same height.
